(19) United States
(12) Patent Application Publication
(10) Pub. No.: US 2016/0181456 A1
(43) Pub. Date: Jun. 23, 2016

(54) Low-Cost and High-Efficiency Tandem Photovoltaic Cells

(71) Applicant: Yong-Hang Zhang, Scottsdale, AZ (US)

(72) Inventor: Yong-Hang Zhang, Scottsdale, AZ (US)

(21) Appl. No.: 14/978,323

(22) Filed: Dec. 22, 2015

Related U.S. Application Data
(60) Provisional application No. 62/095,436, filed on Dec. 22, 2014.

(51) Int. Cl. H01L 31/0725; H01L 31/0216; H01L 31/0236; H01L 31/0368; H01L 31/0376

(52) U.S. Cl. CPC H01L 31/0725; H01L 31/0368; H01L 31/0376; H01L 31/02363; H01L 31/02168

(57) ABSTRACT

Tandem solar cells are provided that are more cost-efficient manner and can reach much higher power conversion efficiency compared to previous technologies. In some aspects, a tandem solar cell includes a first subcell configured to absorb a first portion of a solar spectrum, wherein at least one layer of the first subcell is polycrystalline, and a second subcell configured to absorb a second portion of the solar spectrum, wherein the second subcell is electrically connected to the first subcell through a conductive contact, and includes at least one textured surface.

### CROSS-REFERENCE TO RELATED APPLICATIONS

This application is based on, and incorporates herein by reference, in its entirety, U.S. Application Ser. No. 62/095,436 filed on Dec. 22, 2014 and entitled “LOW-COST AND HIGH-EFFICIENCY TANDEM PHOTOVOLTAIC CELLS.”

### STATEMENT REGARDING FEDERALLY SPONSORED RESEARCH

This invention was made with government support under DOE Cooperative Agreement No. DE-EE0004946 awarded by the U.S. Department of Energy. The government has certain rights in the invention.

### BACKGROUND OF THE INVENTION

The field of the invention is directed to systems and methods for converting solar energy. More particularly, the invention relates to solar cells.

The overall global market share of electricity supply generated by solar cells is still very small, far below 1%, due to high cost. Since solar cells are also an ideal means for electricity generation for those remote areas that have no access to an electrical grid, it is highly desirable to find effective ways to further reduce the overall cost of solar cells and integrate them with other functionalities to realize a much increased overall efficiency of utilizing free solar energy in developing countries. For instance, solar cells may be combined with water heaters to utilize the low grade thermal energy for household hot water applications.

Many initiatives have been aimed at reducing the total installed cost of solar energy systems. Some of the most effective approaches to reach this goal have aimed at increasing photovoltaic (“PV”) solar cell efficiency and cutting the amount of materials utilized, in order to reduce the total balance of system (“BOS”) cost.

Currently, some of the most promising solar cells technologies include silicon (“Si”) and cadmium telluride (“CdTe”) thin-film solar cells, which provide, in addition to lower cost, high module efficiencies and the shortest energy payback time. CdTe technologies use little semiconductor materials and few production processes along with very large manufacturing throughput, in contrast to traditional crystalline Si-based mainstream solar cell technologies. However, despite commercial successes, neither Si-based solar cells nor CdTe thin film solar cells are cost effective enough to reach grid parity. That is, these technologies are not efficient enough for rapid market share capture as compared to more traditional energy generation approaches, such coal and other energy sources.

It is therefore highly desirable to further reduce the solar cell module cost through both the increase of the power conversion efficiency and the reduction of the manufacturing cost.

### SUMMARY OF THE INVENTION

The present disclosure overcomes aforementioned drawbacks by providing cost-effective solar cells that can achieve much higher power conversion efficiency compared to previous technologies. In particular, tandem solar cell embodiments introduced herein include structures that generally comprise two subcell components electrically connected using a conductive contact, such as a point contact or tunnel junction structure, wherein each subcell is configured to efficiently convert a different portion of a solar spectrum without appreciably limiting the other.

As will be described, provided embodiments can advantageously combine low-cost thin-film II-VI solar cell technologies and those of conventional Si solar cells to achieve enhanced performance. For instance, in one tandem solar cell configuration, the top, or front, subcell includes a wide bandgap polycrystalline absorbing material, such as a II-VI material, while the bottom, or back, subcell includes a semiconducting material, such as silicon, with subcells being integrated in a structure that is uniquely capable of reaching the high efficiency required for grid parity.

In one aspect of the present disclosure, a tandem solar cell is provided that includes a first subcell configured to absorb a first portion of a solar spectrum, wherein at least one layer of the first subcell is polycrystalline, and a second subcell configured to absorb a second portion of the solar spectrum, wherein the second subcell is electrically connected to the first subcell through a conductive contact.

In another aspect of the present disclosure, a tandem solar cell is provided that includes a first subcell configured to absorb a first portion of a solar spectrum, and a second subcell configured to absorb a second portion of the solar spectrum, wherein the second subcell includes at least one textured surface and is electrically connected to the first subcell through a conductive contact.

The foregoing and other aspects and advantages of the invention will appear from the following description. In the description, reference is made to the accompanying drawings that form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 shows a schematic of an example tandem solar cell, in accordance with embodiments of the present disclosure

FIG. 2 illustrates one embodiment of the tandem solar cell shown in FIG. 1, in accordance with aspects of the present disclosure.

FIG. 3 illustrates another embodiment of the tandem solar cell shown in FIG. 1, in accordance with aspects of the present disclosure.

FIG. 4 illustrates yet another embodiment of the tandem solar cell shown in FIG. 1, in accordance with aspects of the present disclosure.

FIG. 5 is a graph showing efficiencies versus minority carrier lifetime for a tandem solar cell, in accordance with aspects of the present disclosure.

### DETAILED DESCRIPTION OF THE INVENTION

The present disclosure provides a novel tandem solar cell for converting solar radiation to electrical energy, with embodiments that include a numbers of innovative features and elements that improve upon previous technologies. In particular, although many prior attempts have been made to integrate Silicon-based (“Si”) solar cell and thin-film solar cell technologies, no appreciable successes have been reached on account of the lack of materials with all the appropriate properties, as well as the challenges of effectively combining different cell elements to achieve high efficiency. Therefore, the present disclosure provides various tandem solar cell implementations that utilize a combination of subcell components tailored to absorb specific portions of the solar spectrum in manner that is efficient and cost-effective.

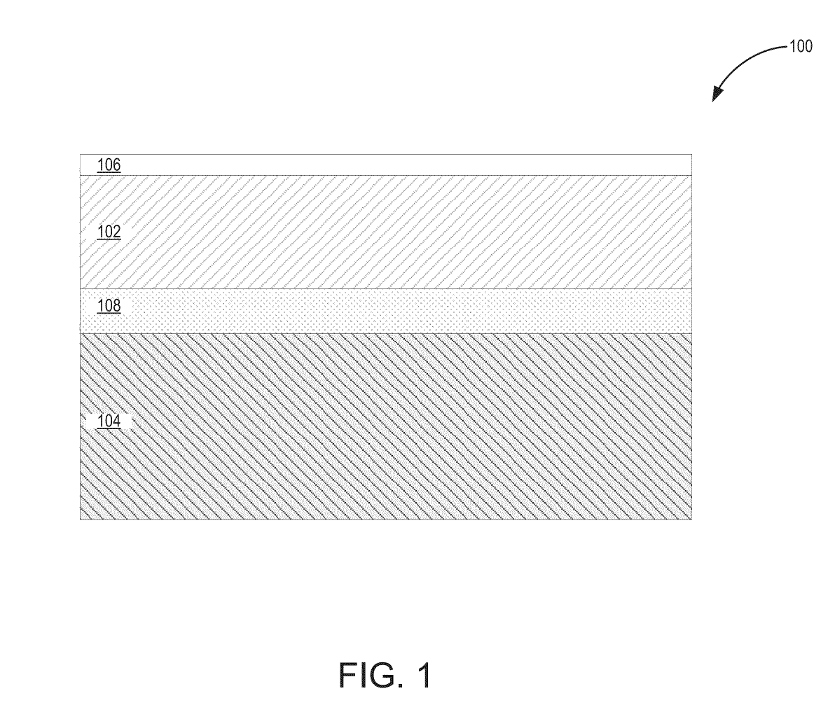

Referring specifically to FIG. 1, a schematic diagram for a tandem solar cell 100, in accordance with the various embodiments of the present disclosure, is shown. In general, the tandem solar cell 100 can include a front, or top subcell 102, a back, or bottom subcell 104, and a coupling layer 106 arranged therebetween. The tandem solar cell 100 also includes a cover or protective layer 108.

As will be described, the top subcell 102 may include any number thin film layers or structures, including at least one absorber layer configured to absorb a first portion of the solar spectrum incident on the tandem solar cell 100. In some embodiments, the absorber layer(s) may be constructed using polycrystalline materials, and preferably polycrystalline II-VI materials. As may be appreciated, such polycrystalline top subcell 102 implementations are in contrast to previous multi junction solar cell technologies, the latter utilizing single crystal materials deposited on top of a silicon (“Si”) base, for instance.

In some aspects, the absorbing materials in the top subcell 102 may be configured with a bandgap in a range between 1.53 eV and 1.73 eV, although other values may be possible. Specifically, band gaps that provide a current match with bottom subcell 104, as will be described, may be particularly desirable. In general, II-VI materials in the top subcell 102 can include various binary, ternary, quaternary alloys, and so forth. Non-limiting examples of absorber layers can include MgₓCd₁₋ₓTe, ZnₚCd₁₋ₚTe, Cu₂Zn(Sn_{y},Ge_{1-y})(Sₓ,Se₁₋ₓ) (“CZTGeSSe”), although other materials or compositions may be possible.

In some aspects, the absorber layers in the top subcell 102 can have thicknesses in a range between 0.2 μm and 1 μm, although other values may be possible. Advantageously, thinner absorber layers have a higher built-in internal electric field for better carrier extraction. This property is highly desirable particularly when using polycrystalline materials, in accordance with aspects of the present disclosure, due to its high non-radiative recombination rate resulting from defects in the bulk or on the surface or interface of grain boundaries. In addition, thinner absorber layer thicknesses may also be preferable in order reduce the total number of defects, such as non-radiative recombination centers, and therefore increases overall conversion efficiency, as all the photons are effectively trapped and eventually absorbed inside the solar cell by the scattering at the textured interfaces, as will be described. Furthermore, thinner absorber layers result in much reduced material consumption, and hence lower processing costs. For example, reducing absorbing layers from the typical 3 μm thickness down to 0.2-1 μm, can result in a 93% to 66% reduction. This proven advantage has not been used in current commercial CdTe thin-film solar cell technology.

In some designs, as will be described, absorber layers may be configured using double heterostructure layers, with a doping profile such that the absorber layer is lightly doped and inserted between two more heavily doped barrier layers. Such a double heterostructure design can provide a very strong confinement of photogenerated carriers, with long carrier lifetimes, leading to increased solar cell efficiency. For instance, an ultrathin double-heterostructure, can include CdS/MgₓCd₁₋ₓTe/Mg_{y}Cd_{1-y}Te (y>x) or CdS/ZnₚCd₁₋ₚTe/Zn_{q}Cd_{1-q}Te (p>q), although other material compositions and configurations may be possible.

Referring again to FIG. 1, the tandem solar cell 100 also includes a bottom subcell 104, to include amorphous or crystalline semiconductor materials. In some embodiments, conventional or thin-Si heterojunction can be implemented in the bottom subcell 104. In addition, in some aspects, the bottom subcell 104 can include one or more textured surfaces. Such textured surfaces can provide back scattering for the top subcell 102, such as a top subcell 102 implementing II-VI materials, as well as well as light scattering for the bottom subcell 104. In this manner, a stronger light trapping can take place, allowing use of much thinner absorber layer thicknesses, as described, of both top and bottom subcells. As mentioned, non-radiative recombination processes can thus be minimized, enabling higher cell efficiency.

As shown in FIG. 1, in addition to a protective layer 106, the tandem solar cell 100 may include a connecting layer 108, linking the top subcell 102 and bottom subcell 104. As be described, the connecting layer 108, may include various materials, structures and compositions, including materials and configurations for electrically connecting the subcells.

In accordance with aspects of the present disclosure, a novel approach for electrically connecting the subcells is provided. In particular, a conductive contact implemented in the conducting layer 108 may be achieved using point contacts, of any shapes, sizes, spacings, spatial distributions and configurations. In particular, the point contacts can include i) metallic contacts, ii) semiconductor type-II quantum dot contacts, iii) conductive oxide contacts, and iv) tunnel junction contacts involving diffused group-II and/or group-VI elements of a polycrystalline or amorphous II-VI semiconductor subcell layers, and so forth, for example through openings in a passivation layer. The last approach may be more cost effective given compatibility with existing manufacturing processes of II-VI thin-film solar cells. Also, in addition to limited shadow areas, point contacts enable use of cheaper, non-transparent metals. Therefore, conductive contact achieved in the manner afforded by the present disclosure can minimize optical absorption, and thereby increase cell efficiency.

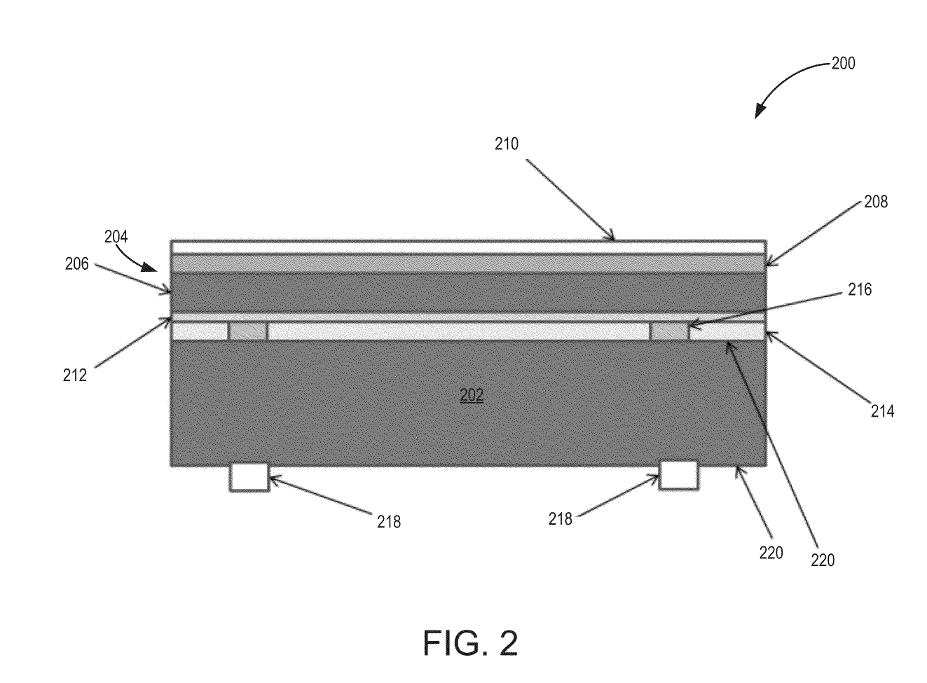

Specifically with reference to FIG. 2, one embodiment of a tandem solar cell 200 is provided. The tandem solar cell 200 includes a bottom subcell 202 and a top subcell 204 that are electrically connected. In some implementations, the bottom subcell 202 includes Si, and the top subcell 204 includes an absorbing layer 206, to include a wide-band gap polycrystalline absorber layer such as MgCdTe or ZnCdTe. Other materials and compositions are also possible. As shown, in some aspects, top subcell 204 may also include a window layer 208, for example, including n-type CdS, as well as an anti-reflective coating, and is covered by protective glass 210. The top subject 204 may also include a transparent conducting layer 212, such as an oxide layer.

As shown in FIG. 2, the bottom subcell 202 and top subcell 204 are separated by a passivation layer 214, which may include SiOₓ. The passivation layer 214 includes include one or more electrical contacts 216 formed therein. As described, the electrical contacts 216 can include point contacts, such as metal, type-II HS, quantum dot, and other contacts. As shown, the electrical contacts 216 connect the bottom subcell 202 through the passivation layer 214, and make an electrical contact to the transparent conducting layer 212. The bottom subcell 202 also includes bottom electrical contacts 218, as well as a number of textured surfaces 220.

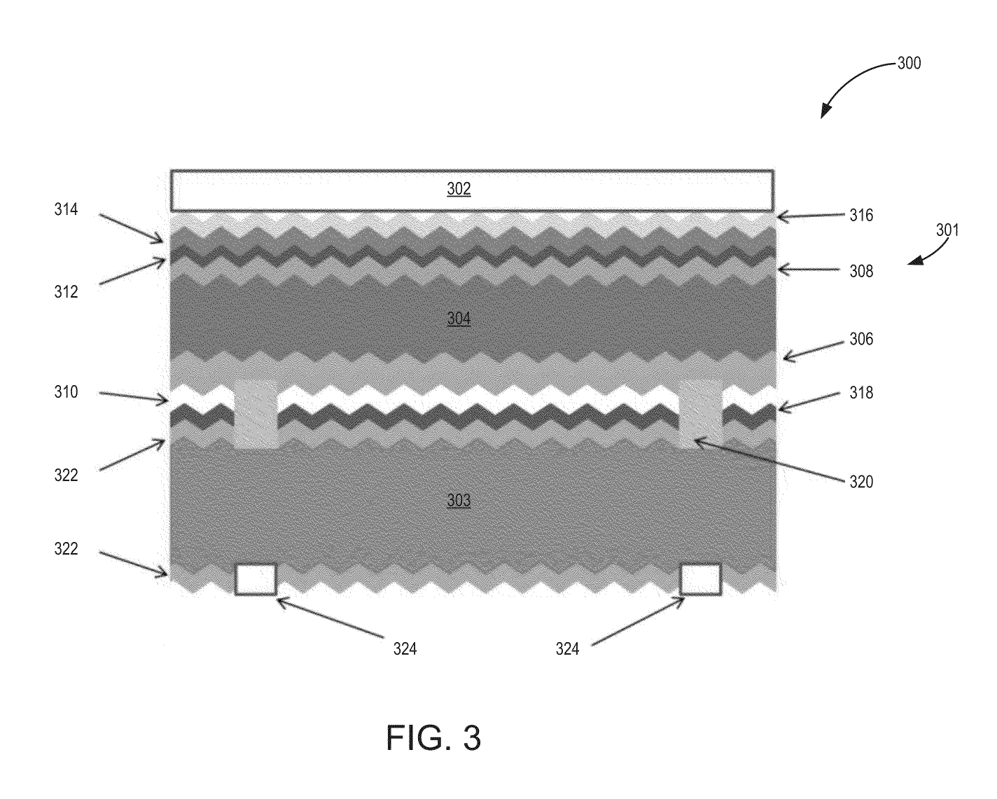

Specifically with reference to FIG. 3, another embodiment of a tandem solar cell 300 is provided. Similar to the example of FIG. 2, the tandem solar cell 300 includes electrically connected top subcell 301, which utilizes polycrystalline II-VI materials, and a bottom subcell 303, which utilizes Si, the tandem solar cell 300 being covered by a protective glass 302.

In particular, the top subcell 301 may be formed using an absorber layer 304, which may include p-MgₓCd₁₋ₓTe, ZnₚCd₁₋ₚTe, p-Cu₂Zn(Sn_{y},Ge_{1-y})(Sₓ,Se₄₋ₓ), as well as other preferably wide band-gap absorber materials. As shown, the absorber layer 304 may be arranged on a barrier layer 306. In addition, the absorber layer 304 may also be adjacent to a window layer 308, for example a n-CdS layer, forming a dual-layer heterostructure, as described. Non-limiting barrier layer 306 examples can include p-Mg_{y}Cd_{1-y}Te or Zn_{q}Cd_{1-q} Te materials, in dependence of the absorber material utilized. For instance, a p-MgₓCd₁₋ₓTe absorber would be adjacent to a p-Mg_{y}Cd_{1-y}Te barrier, and so on. As shown, the barrier layer 306 may also be adjacent to a transparent conductive layer 310 placed distally with respect to the incident radiation, wherein the transparent conductive layer 310 may include a low resistance materials, such as transparent conductive oxide (TCO) or p-ZnTe.

As shown, in some implementations, the top subcell 301 may also include a high restive layer 312, such as TCO, SnO₂, and a low resistive layer 314, such as TCO. In addition, the top subcell 301 may further include an anti-reflective (AR) coating 316 providing strong light trapping to enhance the optical absorption. In some aspects, at least one or all of the transparent conductive layer 310, the barrier layer 306, the low resistive layer 314, and the high resistive layer 312 can be textured.

The tandem solar cell 300 also includes a passivation layer 318 placed between the top subcell 301 and bottom subcell 303. In addition, electrical contacts 320 may be formed therein such that an electrical contact is achieved between the top subcell 301 and bottom subcell 303. As illustrated, the electrical contacts 320 may traverse or contact a number of layers, included the passivation layer 318, the transparent conducting layer 310 and the barrier layer 306. By way of example, electrical contacts 320 can include point contacts, such as metal, type-II HS, quantum dot, and other contacts. In addition, the bottom subcell 303 includes one or more textured surfaces 322, as well as bottom contacts 324.

One non-limiting example of tandem solar cell 300 includes: Si/SiOₓ/TCO/p-Mg_{y}Cd_{1-y}Te (or Zn_{q}Cd_{1-q}Te)/p-MgₓCd₁₋ₓTe (or ZnₚCd₁₋ₚTe)/n-CdS/TCO (or SnO₂) TCO (or ITO)/AR coating. Another non-limiting example includes Si/SiOₓ (or SiNₓ)/TCO (or p-ZnTe)/p-Cu₂Zn(Sn_{q},Ge_{1-q})(Sₚ,Se₁₋ₚ)/p-Cu₂Zn(Sn_{y},Ge_{1-y})(Sₓ,Se₄₋ₓ)/n-CdS/TCO (or SnO₂)/TCO (or ITO)/AR coating; Such structure offers several advantages including that both Si and CZTGeSSe subcells use only earth-abundant and non-toxic elements, reducing fabrication costs.

As described, both surfaces of a Si-based bottom subcell 303 can be textured, as well as all the interfaces of the polycrystalline CZTGeSSe-based top subcell 301 and the top surface of the anti-reflective coating 316, providing strong light trapping to enhance the optical absorption in the CZTGeSSe-based subcell. Therefore, only a very thin layer (for example, 0.2 μm) would be needed for the top subcell 301, a dramatic cost-reduction from conventional 2 μm thick cells. As described, the use of point contacts to connect top and bottom subcells enables the use of non-transparent metal contacts. Due to the limited shadow area of these point contacts, the absorption of the metal contacts will likely be very small, on the order of a few percent of incoming sunlight. In addition, the integration of II-VI materials on Si enables the formation of diffused tunnel junctions at the heterostructure interfaces. Such tunnel junctions have advantageously low optical loss and series resistance. Moreover, the use of heterojunctions for the bottom Si subcell may also reduce the Si usage.

A preliminary cost analysis shows that such a tandem cell design, in accordance with FIG. 3, can drastically reduce the overall balance of system (“BOS”) cost. By way of comparison, a traditional CdTe thin-film solar cell includes an overall material and process per area cost of CdTe thin-films at about 22% of the overall cost for the complete solar cell on a glass substrate. This number is expected to be even lower for a CZTGeSSe-based tandem solar cell, for instance, because: (i) manufacturing of CdTe is based on vacuum deposition. By contrast, successful fabrication of CZTGeSSe using nanocrystal inks, demonstrated by the inventors, is potentially less expensive and less energy-consuming compared to vacuum deposition. In addition, CZTGeSSe-based cells utilize only earth-abundant elements while CdTe technologies do not.

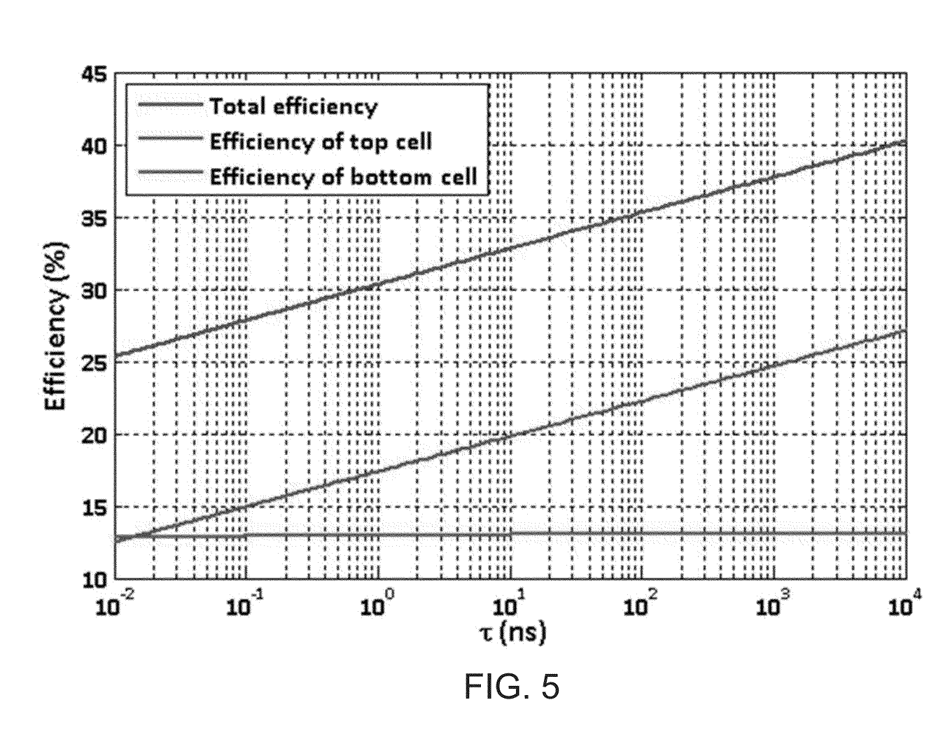

Modeling results show that the tandem cell proposed herein has a theoretical efficiency limit over 40% at one sun, as illustrated in FIG. 5. In practice, the efficiency can be over 30% even if the minority carry lifetime is on the order of nanoseconds, a value that is quite typical for polycrystalline materials. It is reasonable to anticipate that the 20% to 30% cost increase for producing a tandem cell can result in a more than 50% increase in efficiency and an even greater reduction in the BOS cost. Combined with a low-cost optical concentrator, the effect cost of the solar cells can be further reduced up to 50 times.

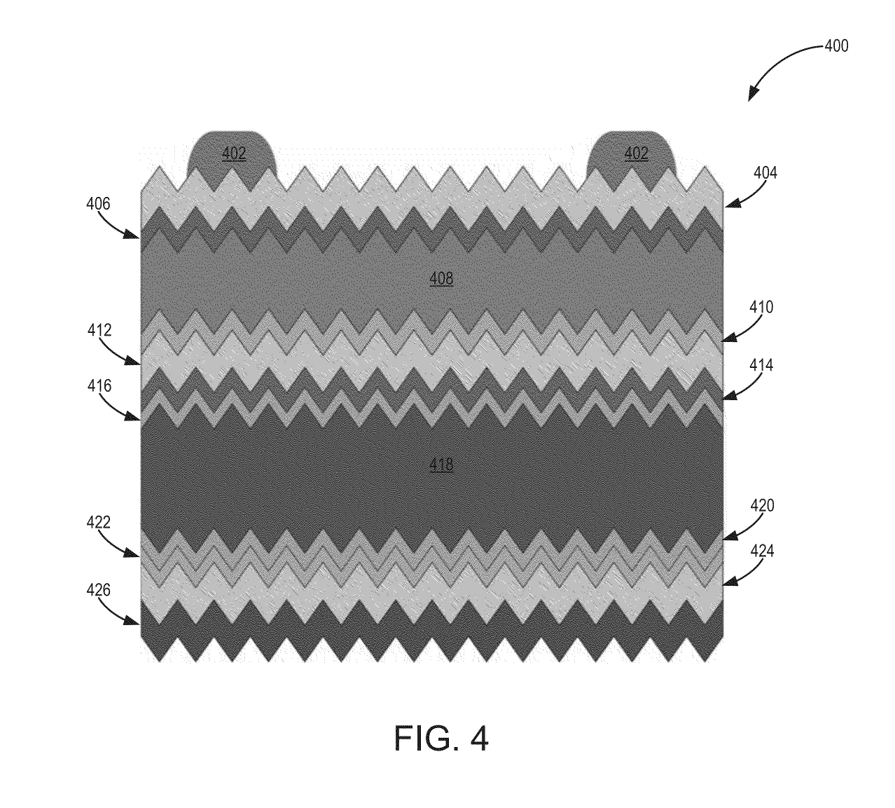

Specifically with reference to FIG. 4, yet another embodiment of a tandem solar cell 400 is provided. In general, the tandem solar cell 400 includes a top subcell, including II-VI materials, and bottom subcell, that includes Si, wherein the top and bottom subcells are electrically connected by a tunnel junction. As shown, the structure of the tandem solar cell 400 may include a top contact 402 (e.g. Ag), a top transparent conducting layer (e.g. TCO), a window layer 406 (e.g. CdS(n)), a top absorbing layer 408 (e.g. MgCdTe (p)), a barrier layer 410 (e.g. MgCdTe (p⁺)), a middle transparent conducting layer 412 (e.g. TCO), a first textured layer 414 (e.g. a-Si:H (n⁺)), a first insulating layer 416 (e.g. a-Si:H (i)), a bottom absorbing layer 418 (e.g. c-Si (n)), a second insulating layer 420 (e.g. a-Si:H (i)), a second textured layer 422 (e.g. a-Si:H (p⁺)), a bottom transparent conducting layer 424 (e.g. TCO), and a bottom contact 426 (e.g. Ag).

As shown in FIG. 4, the top subcell of the tandem solar cell 400 may include a MgCdTe absorber layer, which, for example, can be Mg_{0.15}Cd_{0.85}Te and configured to have a bandgap around 1.73 eV, while the bottom subcell may include a crystalline Si layer. In some aspects, use of a thin CdTe/MgCdTe double-heterostructure for polycrystalline II-VI subcell minimizes non-radiative recombination at the surfaces, and thereby dramatically increases the power conversion efficiency. The tunnel junction is implemented between a-Si:H and MgCdTe layers in the tandem solar cell.

In addition, the bottom subcell can be a modified amorphous silicon/crystalline silicon heterojunction (SHJ) solar cell. This type of cell configuration was demonstrated to achieve an open-circuit voltage of V_{oc}=750 mV and implied-V_{oc}=767 mV. One drawback of this design as a stand-alone device is that the amorphous silicon (a-Si:H) front passivation and emitter layers absorb blue light parasitically. However, by integration into a II-VI/silicon tandem solar cell, in accordance with the present disclosure, such parasitic absorption is a non-issue. This is because all of the blue light will be absorbed by the top subcell cell and so the a-Si:H layers in the bottom subcell can be optimized to achieve maximum V_{oc} and fill factor (FF), without compromising the short-circuit current (J_{sc}). In addition, both surfaces of the Si bottom subcell may be textured, and thus all the interfaces of the polycrystalline II-VI thin-film top cell may be textured as well, providing optimal light scattering to enhance the effective optical thickness of both subcells.

As shown in FIG. 4, the bottom subcell is an inverted SHJ solar cell compared to its normal orientation, so that the p-type a-Si:H emitter is at the rear of the solar cell and the n-type a-Si:H contact is at the front with respect to incident sunlight. This facilitates the integration with the MgCdTe top subcell, since a p-n tunnel junction is required between the two subcells and it is preferable to have the MgCdTe p-type layer at the back of the top cell because it absorbs more blue light (likely parasitically) than the wider-bandgap CdS n-type layer.

With reference to the tunnel junction between the a-Si:H n⁺ and MgCdTe p⁺ layers, as shown in FIG. 4, a thin transparent conductive oxide (TCO) layer is inserted therebetween to ensure a sufficiently low-resistance tunnel junction. By way of example, indium tin oxide (ITO) and zinc oxide (ZnO) are suitable candidates that form good contact to both a-Si:H and MgCdTe.

The present invention has been described in terms of one or more preferred embodiments, and it should be appreciated that many equivalents, alternatives, variations, and modifications, aside from those expressly stated, are possible and within the scope of the invention.

1. A tandem solar cell comprising:
a first subcell configured to absorb a first portion of a solar spectrum, wherein at least one layer of the first subcell is polycrystalline; and
a second subcell configured to absorb a second portion of the solar spectrum, wherein the second subcell is electrically connected to the first subcell through a conductive contact.

2. The solar cell of claim 1, wherein the first subcell includes an absorbing layer.

3. The solar cell of claim 2, wherein the absorbing layer has a thickness in a range of 0.1 micrometers to 2 micrometers.

4. The solar cell of claim 1, wherein the first subcell is defined by a first bandgap energy and the second subcell is defined by a second bandgap energy.

5. The solar cell of claim 1, wherein the second subcell includes at least one textured surface.

6. The solar cell of claim 1, wherein the second subcell includes at least one of an amorphous silicon or crystalline silicon layer.

7. The solar cell of claim 1, wherein the conductive contact includes a point contact.

8. The solar cell of claim 1, wherein the conductive contact includes one of a metallic contact, a semiconductor quantum dot contact, a conductive oxide contact, or a tunnel junction contact.

9. The solar cell of claim 8, wherein the tunnel junction contact includes one or more of a diffused group-II material of a polycrystalline or an amorphous semiconductor, or a diffused group-VI material of the polycrystalline or the amorphous semiconductor.

10. The solar cell of claim 9, wherein the polycrystalline or amorphous semiconductor is a II-VI semiconductor.

11. The solar cell of claim 1, the solar cell further comprising at least one antireflective coating.

12. A tandem solar cell comprising:
a first subcell configured to absorb a first portion of a solar spectrum; and
a second subcell configured to absorb a second portion of the solar spectrum, wherein the second subcell includes at least one textured surface and is electrically connected to the first subcell through a conductive contact.

13. The solar cell of claim 12, wherein the first subcell includes an absorbing layer.

14. The solar cell of claim 12, wherein the absorbing layer has a thickness in a range of 0.1 micrometers to 2 micrometers.

15. The solar cell of claim 12, wherein the first subcell is defined by a first bandgap energy and the second subcell is defined by a second bandgap energy.

16. The solar cell of claim 12, wherein the second subcell includes at least one of an amorphous silicon or crystalline silicon layer.

17. The solar cell of claim 12, wherein the conductive contact includes a point contact.

18. The solar cell of claim 12, wherein the conductive contact includes one of a metallic contact, a semiconductor quantum dot contact, a conductive oxide contact, or a tunnel junction contact.

19. The solar cell of claim 18, wherein the tunnel junction contact includes one or more of a diffused group-II material of a polycrystalline or an amorphous semiconductor, or a diffused group-VI material of the polycrystalline or the amorphous semiconductor.

20. The solar cell of claim 19, wherein the polycrystalline or amorphous semiconductor is a II-VI semiconductor.

21. The solar cell of claim 12, the solar cell further comprising at least one antireflective coating.
